(19) United States
(12) Patent Application Publication
(10) Pub. No.: US 2007/0134847 A1
(43) Pub. Date: Jun. 14, 2007

(54) Die-attaching paste composition and method for hardening the same

(76) Inventors: Byoung-Un Kang, Gyeonggi-do (KR); Jae-Hoon Kim, Seoul (KR); Joon-Mo Seo, Gyeonggi-do (KR); Tae-Hyun Sung, Seoul (KR); Kyung-Tae Wi, Gyeonggi-do (KR)

Correspondence Address: JONES DAY, 222 EAST 41ST ST, NEW YORK, NY, 10017, US

(21) Appl. No.: 11/633,132

(22) Filed: Dec. 1, 2006

(30) Foreign Application Priority Data
Dec. 8, 2005 (KR) 10-2005-0119292

(51) Int. Cl. H01L 21/00

(52) U.S. Cl. 438/118

(57) ABSTRACT

Disclosed are a die-attaching paste composition and a method for hardening the same. The present invention provides the die-attaching paste composition applied at a thickness of 200 μm or less on a printed circuit board (PCB), including liquid or solid epoxy, acrylate, a flexing agent, an organic filler and a UV-initiator. The method for hardening a die-attaching paste of the present invention includes carrying out a B-staging process by irradiating a UV-ray to the die-attaching paste composition. According to the present invention, a processing time may be more shortened and storage of the die-attaching paste may be more significantly improved when a B-staging process using UV rays is applied than when a conventional thermal crosslinking method is used, and therefore a manufacturing cost in the conventional assembly industries may be decreased. Also, the B-staging process may be uniformly carried out and physical properties of the die-attaching paste may be adjusted to desired characteristics since the UV exposure to the die-attaching paste is easily controlled.

### BACKGROUND OF THE INVENTION

1. Field of the Invention

The present invention relates to a die-attaching paste composition and a method for hardening the same, and more particularly to a die-attaching paste composition which includes a UV initiator and is capable of carrying out a B-staging process by irradiating UV rays, and a method for hardening the same.

2. Description of the Related Art

In one pattern of semiconductor packages, a semiconductor die or chip is electrically connected to a substrate, and also mechanically connected by means of an adhesive. The substrate is connected to other electric elements or external power sources. A manufacturing process may be carried out in series, or otherwise, a substrate may be manufactured using an adhesive for the mechanical attachment, and maintained to a predetermined scheduled period.

If the manufacturing process is carried out in series, an adhesive is applied onto a substrate, a semiconductor chip comes in contact to the adhesive, and then the adhesive is hardened by imposing heat, or heat and pressure. An suitable adhesive may be in a solvent-free liquid phase, and a paste or solid phase. If the adhesive is in a liquid or paste phase, the adhesive is solidified while being hardened by heating. If a manufacturing process is suspended after the adhesive is applied to a substrate and a final assembly process is postponed until a later point of time, the adhesive should be in a solid shape in order to be preserved intact. The solid adhesive has advantages that a bleeding phenomenon is minimally present or not present at all, and a bondline, namely interfacial thickness and tilt between a chip and the adhesive may be controlled satisfactorily.

For some applications of the semiconductor packages, a paste adhesive is preferred to a film adhesive due to problems in the process, but it is required to control a solid bondline and a fillet. In this case, known adhesives may be used as the B-stageable adhesive. If adhesive materials are solid, the solid is dispersed or dissolved in a solvent to form a paste, and then the paste is applied onto a substrate. Subsequently, a solid state of the adhesive, which is not hardened, is left on the substrate by heating the adhesive to evaporate the solvent. If adhesive materials are liquid or paste, the adhesive is distributed on a substrate, and then the substrate is heated to partially harden the adhesive into a solid state.

A thermal initiator or a reactive diluent has been used in the art for the purpose of accomplishing a B-staging process by thermally hardening a die-attaching paste adhesive in a semiconductor process. However, the B-staging process using the conventional thermal hardening has disadvantages that a large amount of time is required and PCB may be warped as the time passes. Also, poor die attachment or soldering may be caused due to the PCB warpage. Also, the poor die attachment remains to be solved since it is difficult to meet an optimal condition for the die attachment, and it is difficult to continuously maintain the optimal condition even though the optimal condition is found. The poor die attachment may adversely affect reliability of the final product. Also, an in-housing printing process has been required for the assembly industries since the die-attaching paste is poor in storage when it is subject to a conventional thermal B-staging process. Also, it is not economical since a printing line should be further installed due to these conventional problems and a printing process be carried out in the printing line, and therefore there has been recognized a need to solve the conventional general problems. Accordingly, there have been ardent attempts to solve the problems presented in the related art, and therefore the present invention was designed based on the above technical background.

### SUMMARY OF THE INVENTION

The present invention is designed to solve the problems of the prior art, and therefore it is an object of the present invention to provide a die-attaching paste composition capable of solving various problems caused in carrying out the B-staging process according to a conventional hardening method using thermal crosslinking, as well as additional problems caused by a poor die attachment and a short storage period of the die-attaching paste, and a method for manufacturing the same.

In order to accomplish the above object, the present invention provides a die-attaching paste composition applied in a thickness of 200 μm or less on a printed circuit board (PCB), including 50 to 70% by weight of liquid or solid epoxy; 3 to 10% by weight of acrylate; 25 to 40% by weight of a flexing agent; and 5 to 30% by weight of an organic filler, wherein the composition further includes 1 to 7 phr of a UV-initiator on the basis of the total content of the die-attaching paste composition.

If the die-attaching paste according to the present invention is applied in a thickness of greater than 200 μm on the PCB unlike the above, the paste may not be maintained in a desired shape due to its fluidity when it is printed, or final products may be inferior in quality since an overflow may be caused upon the die attachment.

The UV initiator is preferably selected from the group consisting of 2-hydroxy-2-methyl-1-phenyl-1-propanone, alphadimethoxy-alpha-phenylacetophenone, 2-hydroxy-1[4-(2-hydroxyethoxy)phenyl]-2-methyl-1-propanone, methylbenzoylformate, diphenyl(2,4,6-trimethylbenzoyl)-phosphine oxide, 1-hydroxy-cyclohexyl-phenyl-ketone and bis(2,4,6-trimethylbenzoyl)-phenylphosphineoxide, and they may be used alone or in combinations thereof.

Storage of the die-attaching paste, as well as a die shear strength and MRT (Moisture Resistance Test) are all improved if a content of the UV initiator meets the numerical limit.

In order to accomplish the above object, the present invention provides a method for hardening a die-attaching paste, including steps of applying the above-mentioned die-attaching paste composition on a printed circuit board (PCB) in a layered structure, and carrying out a B-staging process by irradiating UV rays to the die-attaching paste layer applied in a layered structure.

The UV irradiation is preferably carried out at a dose of 2 to 12 J/cm². The B-staging process may not be carried out if the UV dosage is less than the lower numerical limit, and therefore it is difficult to externally maintain a shape of paste and the paste may be internally aged due to its structural instability, while the die attachment may be not easily carried out since the paste is solidified so strongly if the UV dosage exceeds the upper numerical limit.

### BRIEF DESCRIPTION OF THE DRAWINGS

Other objects and aspects of the present invention will become apparent from the following description of embodiments with reference to the accompanying drawings. However, it should be understood that the description proposed herein is just a preferable example for the purpose of illustrations only, not intended to limit the scope of the invention. In the drawing:

FIG. 1 is a schematic view showing that a B-staging process is carried out by irradiating UV rays to a die-attaching paste layer applied on a printed circuit board (PCB).

### DESCRIPTION OF THE PREFERRED EMBODIMENT

Hereinafter, preferred embodiments of the present invention will be described in detail referring to the accompanying drawings. However, the description proposed herein is just a preferable example for the purpose of illustrations only, not intended to limit the scope of the invention, so it should be understood that other equivalents and modifications could be made thereto without departing from the spirit and scope of the invention. The preferred embodiments of the present invention will be described in detail for the purpose of better understandings, as apparent to those skilled in the art.

Materials constituting components of a die-attaching paste composition according to the present invention were weighed, respectively, and the prepared materials were homogeneously mixed and stirred at a room temperature for 48 hours to obtain a paste. The paste was then printed on a printed circuit board (PCB), and a B-staging process was carried out by irradiating UV rays.

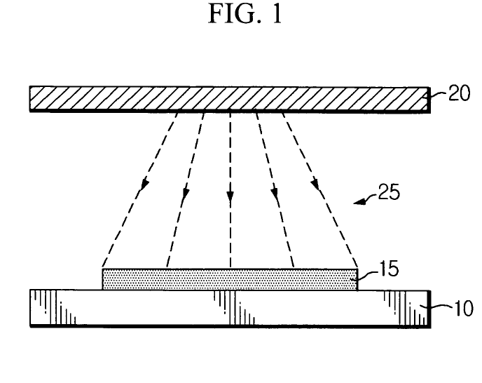

FIG. 1 is a schematic view showing a B-staging process which is carried out by irradiating UV rays to a die-attaching paste layer applied onto PCB.

As show in FIG. 1, the B-staging process is carried out by irradiating UV rays 25 to a die-attaching paste layer 15 applied onto a PCB 10, using a UV lamp 20. At this time, the UV irradiation system may be constituted in a batch or conveyor type, and the UV lamp 25 may selectively use various suitable sources of light, for example arc, fusion, etc, depending on characteristics of the materials. The UV rays are irradiated to the entire die-attaching paste layer 25, and its intensity and dosage may be adjusted in consideration of an optimized condition for a UV absorption wavelength of a UV initiator.

### Comparative Examples 1 to 3 and Embodiments 1 and 2

The compositions were classified into Comparative examples 1 to 3 and Embodiments 1 and 2, depending on the varying UV dosage, and evaluated for their physical properties, such as storage, die attaching strength and MRT. The results are listed in the following Table 1.

At this time, a mixture of 2-hydroxy-2-methyl-1-phenyl-1-propanone and diphenyl (2,4,6-trimethylbenzoyl)-phosphine oxide was used as the UV initiator in the die-attaching paste, and its content was 5.5% by weight of the total die attaching paste composition.

Storage Evaluation

In order to evaluate storage of a die-attaching paste, the die-attaching paste was measured for changes of tackiness and heat capacity, measured using suitable methods, after a predetermined period. More particularly, changes of tackiness and heat capacity were measured at time points of 1 and 6 months, respectively. The results are listed in the following Table 1. Meanwhile, the change of the heat capacity was measured using a differential scanning calorimetry (hereinafter, referred to as “DSC”). The DSC is the most general thermal analysis for measuring a transition point of a sample using heat absorption, heat generation or a change of heat capacity by determining a difference of heat flow between a reference sample and a test sample, the difference of heat flow being generally caused when temperatures of the samples are increased or decreased at a constant rate, or maintained at a constant level.

Die Shear Strength Test

A die shear strength test is passed if a die shear strength is 0.5 kgf/cm² or more. A die attachment was carried out on a PCB for a PSR (Photo Solder Resist) AUS308 at 140° C. for 2 seconds under a load of 7 kgf. Meanwhile, a die shear test was measured at a rate of 0.5 mm/s under a load of 500 g, and a temperature of a test bar was maintained at 25° C. At this time, a curing process was carried out at 175° C. for 1 hour. Meanwhile, the die attaching strength was not measured in Comparative example 3 since the die attachment failed.

MRT (Moisture Resistance Test) Evaluation

The MRT was proven to pass (◯) if the paste passed a standard level III (Pb-free Condition) of Joint Electron Device Engineering Council (hereinafter, referred to as “JEDEC”), and proven to fail (x) if the paste did not pass the standard level III. Meanwhile, the MRT was not measured in Comparative example 3 since the die attachment failed.

TABLE 1

| | | | Storage evaluation | | | |
|---|---|---|---|---|---|---|
| | UV | Storage | Tackiness | DSC | Die | |
| | dosage | duration | (Solidity | (Heat | shear | |
| | (J/cm²) | (month) | change) | change) | strength | MRT |
| Comparative | 0 | 1 | −65% | −70% | ◯ | X |
| example 1 | | 6 | −85% | −90% | ◯ | X |
| Comparative | 1 | 1 | −55% | −60% | ◯ | X |
| example 2 | | 6 | −80% | −75% | ◯ | X |
| Embodiment 1 | 4 | 1 | −7% | −15% | ◯ | ◯ |
| | | 6 | −15% | −20% | ◯ | ◯ |
| Embodiment 2 | 7 | 1 | −5% | −10% | ◯ | ◯ |
| | | 6 | −10% | −15% | ◯ | ◯ |
| Comparative | 15 | 1 | −3% | −5% | Not | — |
| example 3 | | | | | attached | |
| | | 6 | −7% | −10% | Not | — |
| | | | | | attached | |

### Comparative Examples 4 and 5 and Embodiment 3

Compositions were classified into Comparative examples 4 and 5 and Embodiment 3, depending on the varying content of the used UV initiator with maintaining the UV dosage at 7 J/cm², unlike Embodiments 1 and 2 and Comparative example 1 to 3 as described above as listed in the following Table 2, and they were evaluated for their physical properties, such as storage, die attaching strength and MRT. The results are listed in the following Table 2.

TABLE 2

| | UV | | | | | |
|---|---|---|---|---|---|---|
| | initiator | | Storage evaluation | | | |
| | (parts | Storage | Tackiness | DSC | Die | |
| | by | duration | (Solidity | (Heat | shear | |
| | weight) | (month) | change) | change) | strength | MRT |
| Comparative | 0.5 | 1 | −30% | −65% | ◯ | X |
| example 4 | | 6 | −75% | −80% | ◯ | X |
| Embodiment 3 | 5.5 | 1 | −5% | −10% | ◯ | ◯ |
| | | 6 | −10% | −15% | ◯ | ◯ |
| Comparative | 8 | 1 | −5% | −7% | Not | — |
| example 5 | | | | | attached | |
| | | 6 | −15% | −20% | Not | — |
| | | | | | attached | |

Numerical changes of solidity and DSC are reference factors for a storage evaluation, which are an aging index. That is to say, the numerical changes of solidity and DSC mean that physical properties of the paste are gradually changed since materials in the paste are hardened and degenerated. Accordingly, it is understood that a lifetime of a product is shortened as the numerical changes increase gradually.

In the above Table 1, Comparative examples 1 to 3 and Embodiments 1 and 2 were classified on the basis of the UV dosage, and, in the above Table 2, Comparative examples 4 and 5 and Embodiment 3 were classified on the basis of the content of the UV initiator. As seen in Table 1 and 2, it was revealed that the numerical changes of the tackiness-related solidity and the DSC in the storage evaluation are exceptionally improved in Embodiments 1 to 3 according to the present invention, compared to those of Comparative examples 1 to 5. And, it was also seen that the die shear strength and the MRT evaluation are proven to pass only in Embodiments 1 and 2 according to the present invention.

As described above, the best embodiments of the present invention are disclosed. Therefore, the specific terms are used in the specification and appended claims, but it should be understood that the description proposed herein is just a preferable example for the purpose of illustrations only, not intended to limit the scope of the invention.

### APPLICABILITY TO THE INDUSTRY

According to the present invention, a processing time may be more shortened (60 to 90 minutes) and storage of the die-attaching paste may be more significantly improved when a B-staging process using UV rays is applied than when a conventional thermal crosslinking method is used, and therefore a manufacturing cost spent by the conventional assembly industries may be decreased. That is to say, a chip mounting process may be carried out, if necessary, since the PCB, on which the die-attaching paste is printed to complete the B-staging process, is piled up in a separate region, and therefore productivity may be effectively enhanced since an expensive printing system is not required and a printing process may be omitted. Also, the B-staging process may be uniformly carried out and physical properties of the die-attaching paste may be adjusted according to desired characteristics since the UV exposure to the die-attaching paste is easily controlled.

What is claimed is:

1. A die-attaching paste composition applied in a thickness of 200 μm or less onto a printed circuit board (PCB), comprising:
50 to 70% by weight of liquid or solid epoxy;
3 to 10% by weight of acrylate;
25 to 40% by weight of a flexing agent; and
5 to 30% by weight of an organic filler,
wherein the composition further comprises 1 to 7 phr of a UV-initiator on the basis of the total content of the die-attaching paste composition.

2. The die-attaching paste composition according to claim 1,
wherein the UV initiator is at least one material or a mixture of at least two materials selected from the group consisting of 2-hydroxy-2-methyl-1-phenyl-1-propanone, alphadimethoxy-alpha-phenylacetophenone, 2-hydroxy-1[4-(2-hydroxyethoxy)phenyl]-2-methyl-1-propanone, methylbenzoylformate, diphenyl(2,4,6-trimethylbenzoyl)-phosphine oxide, 1-hydroxy-cyclohexyl-phenyl-ketone and bis(2,4,6-trimethylbenzoyl)-phenylphosphineoxide.

3. A method for hardening a die-attaching paste, comprising:
applying the die-attaching paste composition as defined in claim 1 onto a printed circuit board (PCB) in a layered structure, and
carrying out a B-staging process by irradiating UV rays to the die-attaching paste layer applied in a layered structure.

4. A method for hardening a die-attaching paste, comprising:
applying the die-attaching paste composition as defined in claim 2 onto a printed circuit board (PCB) in a layered structure, and
carrying out a B-staging process by irradiating UV rays to the die-attaching paste layer applied in a layered structure.

5. The method for hardening a die-attaching paste according to claim 3,
wherein the UV irradiation is carried out at a dose of 2 to 12 J/cm².

6. The method for hardening a die-attaching paste according to claim 4,
wherein the UV irradiation is carried out at a dose of 2 to 12 J/cm².
